(19) United States
(12) Patent Application Publication
(10) Pub. No.: US 2026/0262454 A1
(43) Pub. Date: Sep. 3, 2026

(54) Incorporation Of Arsenic Dopant In Semiconductor Lattice

(71) Applicant: UCL Business Ltd, London (GB)

(72) Inventors: Neil Curson, London (GB); Taylor Stock, London (GB); Steven Schofield, London (GB); Oliver Warschkow, London (GB); Emily Hofmann, London (GB)

(21) Appl. No.: 18/846,814

(22) PCT Filed: Mar. 14, 2023
(86) PCT No.: PCT/GB2023/050596

§ 371 Date: Sep. 13, 2024

(30) Foreign Application Priority Data
Mar. 14, 2022 (GB) 2203496.1

(51) Int. Cl. H10P 32/12; H10P 32/10; H10P 95/90

(52) U.S. Cl. CPC H10P 32/12; H10P 32/171; H10P 95/90

(57) ABSTRACT

A method (100) of incorporating arsenic dopant atoms (5) in defined locations of semiconductor lattice (1), the method (100) comprising: (i) forming (102) a passivation layer (9) on a surface (7) of the semiconductor lattice (1); (ii) selectively removing (104) the passivation layer (9) at one or more incorporation sites (15) to reveal the surface (7) of the semiconductor lattice (1); and (iii) exposing (106) the incorporation sites (15) to a dopant precursor gas (17) such that dopant precursor moieties (17) including arsenic atoms (5) adsorb to the surface (7) of the semiconductor lattice (1) in at least some of the incorporation sites (15), wherein arsenic dopant atoms (5) are incorporated into the lattice (1) at the incorporation sites (15).

The present invention relates to the incorporation of arsenic dopant atoms in a surface of a semiconductor lattice. In particular, the present invention relates to precise placement of arsenic atoms in a scalable manner.

The goal of developing a quantum computer is receiving increasing attention because of the significantly enhanced computational power offered by quantum computers.

In a quantum computer, a quantum bit (also known as a qubit) can encode information. The qubit is similar to a classical bit in that it can adopt a value of 0 or 1, but different from the classical bit in that it can adopt both values simultaneously (in a state known as superposition). The computational power of a quantum computer lies in the superposition.

Qubits are implemented in two state quantum mechanical systems (the states corresponding to 0 and 1). For example, qubits may be implemented by trapping photons, trapping electrons, controlling electron spin, or controlling nuclear spin.

One promising candidate for implementing qubits is using the electron spin of dopant atoms placed in a semiconductor host. In order to address and control the qubits, the dopant atoms must be placed in a precise locations. To date, development has focussed on the placement of phosphorous atoms in a (001) silicon surface. The phosphorus/silicon system is chosen because phosphorus has one additional valence electron compared to silicon and produces a spin ½ hydrogenic defect state that can be used for quantum computing. Phosphorus atoms are also of a similar size to silicon atoms and are thus easily incorporated, and silicon is a well understood system allowing for relatively easy incorporation of phosphorus quantum bit structures with conventional silicon-based electronics.

WO 2019/210370 discloses a methodology of scanning tunnelling microscope (STM) hydrogen-desorption lithography for incorporating phosphorus atoms in silicon. The methodology comprises the steps of: forming one or more lithographic sites on the surface portion, using an STM tip; dosing, at a temperature below 100 K, the surface portion using posphine gas in a manner such that, a portion of the molecules bond to the surface portion; and incorporating one or more phosphorus atoms in a respective lithographic site by transferring an amount of energy to the dopant atoms. The energy may be transferred by thermal annealing or transfer of energy through an STM tip. The number of dopant atoms incorporated in a lithographic site is deterministic and related to the size of the lithographic site.

Current methods of incorporating phosphorus dopant atoms do not allow exact placement of the atoms in controlled positions. Furthermore, dopant atoms are typically only incorporated in around 70% of sites, making the process unsuitable for commercial production on large scales.

Furthermore, dopant atoms may be incorporated in unwanted locations due to imperfections in the formation of lithographic sites.

There is a need for a scalable method of precisely placing single dopant atoms in the surface of a semiconductor lattice in order to form qubits of a quantum computer.

According to an aspect of the invention, there is provided a method of incorporating arsenic dopant atoms in defined locations of semiconductor lattice, the method comprising:
(i) forming a passivation layer on a surface of the semiconductor lattice;
(ii) selectively removing the passivation layer at one or more incorporation sites to reveal the surface of the semiconductor lattice; and
(iii) exposing the incorporation sites to a dopant precursor gas such that dopant precursor moieties including arsenic atoms adsorb to the surface of the semiconductor lattice in at least some of the incorporation sites, wherein arsenic dopant atoms are incorporated into the lattice at the incorporation sites.

The step of exposing the surface to a dopant precursor gas may be performed at room temperature.

The semiconductor lattice may be a group IV semiconductor lattice. The lattice may have a (001) surface. For example, the semiconductor lattice may be a silicon lattice, a germanium lattice of a elemental diamond cubic semiconductor.

The method may include the step of thermal annealing the surface layer to incorporate of the arsenic dopant atom(s) into the semiconductor lattice.

It may be that for a germanium lattice, on adsorption of the dopant precursor moieties, the dopant precursor molecule dissociates and the arsenic atom is incorporated in the semiconductor lattice in a manner that no energy transfer is required.

The method may further comprise: over growing the surface of the semiconductor lattice after the arsenic dopant atoms are incorporated.

The area of each incorporation site may be at most four semiconductor atoms, or at most six semiconductor atoms. The area of each incorporation site may be four semiconductor atoms, and arsenic dopant atoms may be incorporated at 100% of the incorporation sites.

The area of each incorporation site is a semiconductor dimer, and arsenic dopant atoms may be incorporated at 80% of the incorporation sites. The area of each incorporation site may be a single semiconductor atom and arsenic dopant atoms may be incorporated at approximately 10% of the incorporation sites.

The method may further comprise, prior to incorporating the arsenic atoms:
(a) identifying incorporation sites where adsorption of arsine has failed and an atom of the passivation layer has readsorbed;
(b) selectively removing the passivation layer to expose the identified incorporation sites; and
(c) exposing the identified incorporation sites to the dopant precursor gas such that the dopant precursor moieties adsorb to the surface of the semiconductor lattice at the identified incorporation sites.

The method may further comprise:
repeating steps (a) to (c) at least once in an iterative manner; and
(d) incorporating the arsenic atoms into the semiconductor lattice.

The method may further comprise, between step (i) and step (ii): heating the passivation layer to cause diffusion of defects in the passivation layer such that defect group together in pairs; and exposing the passivation layer to a further precursor gas comprising further precursor molecules including the same atoms as the passivation layer, to fill the holes in the passivation layer.

The further precursor gas may comprise phosphorus atoms in addition to the same atoms as the passivation layer. The further precursor gas may comprise posphine PH₃.

The passivation layer may be heated to at least 200° C. to cause diffusion of holes in the passivation layer.

The method may further comprise: forming a second passivation layer on a surface of the semiconductor lattice; selectively removing the second passivation layer at one or more second incorporation sites to reveal the surface of the semiconductor lattice; and exposing the second incorporation sites to a second dopant precursor gas such that second dopant precursor moieties including atoms of a second dopant, different to arsenic, adsorb to the surface of the semiconductor lattice in at least some of at the second incorporation sites, wherein atoms of the second dopant are incorporated into the lattice at the second corporation sites.

The step of selectively removing the passivation layer at one or more incorporation sites to reveal the surface of the semiconductor lattice may be performed by one of: scanning tunnelling microscopy; and electron beam microscopy. The step of selectively removing the passivation layer at one or more incorporation sites to reveal the surface of the semiconductor lattice may be performed by: an array of scanning tunnelling microscopy probes.

The method may further comprise the step of, prior to forming the passivation layer on the surface of the semiconductor lattice, annealing the surface of the semiconductor lattice to form a flat surface on an atomic scale.

The passivation layer may comprise atomic hydrogen.

The dopant precursor gas may comprise arsine AsH₃.

The energy barrier of the diffusion and/or desorption of atoms of the passivation layer may be lower than the energy barrier of desorption of the precursor moieties from the surface of the semiconductor lattice.

Various aspects of the invention can provide placement of dopant arsenic atoms at approximately 100% of lithographic sites, with one and only one dopant arsenic atoms incorporated at the lithographic sites. The dopant arsenic atoms can be placed with greater accuracy than phosphorus atoms, and are incorporated more quickly than other dopants. This suggests embodiment of the invention provide, for the first time, a process that can be expanded to commercial scales for making any number of qubits.

The use of arsenic in embodiments allows for the formation of both qubits, using the ½ electron spin, and qudits (which have more than two states), using the 3/2 nuclear spin.

Embodiments which include a stage of exposing the passivation layer to phosphine (or other suitable precursor gasses) ensure defects in the passivation layer are repaired, so no dopant arsenic atoms may be placed at unwanted locations. This may also be used with other dopants, since the phosphine will desorb from smaller defect sites in the passivation layer, rather than being incorporated into the lattice.

The inventors have found that embodiments using germanium can be performed without the need for annealing, or other energy transfer, to incorporate the dopant atoms. This reduces the probability for deleterious desorption of the donors that is a key limiting factor in the scale up to large numbers of qubits for phosphorus in silicon. It also reduces the risk of migration of incorporated dopant atoms away from their desired location.

The inventors have also surprising found that, in embodiments where the lithographic site is only a single silicon atom, performing the iterative process can allow one and only one dopant atom to be placed with accuracy at a single atomic site.

Embodiments of the invention will now be described, by way of example only, with reference to the accompanying drawings in which:

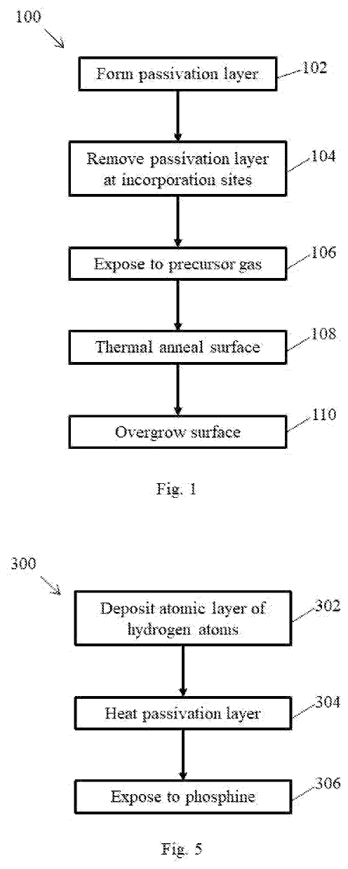

FIG. 1 shows a flow diagram of a method for embedding a dopant atom in a surface of a semiconductor lattice;

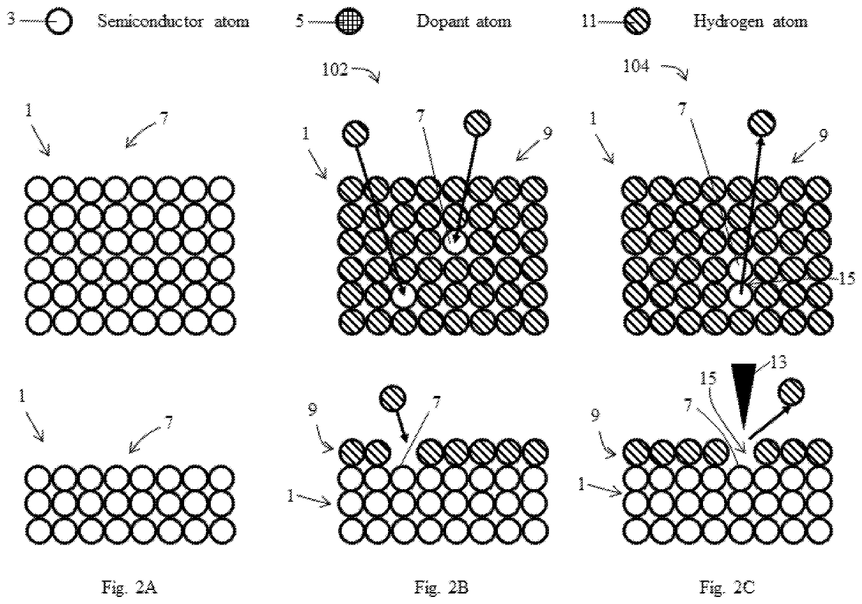

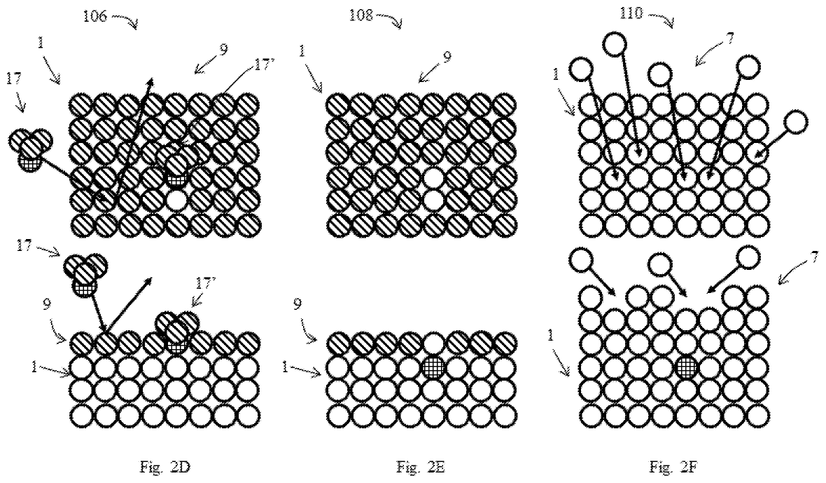

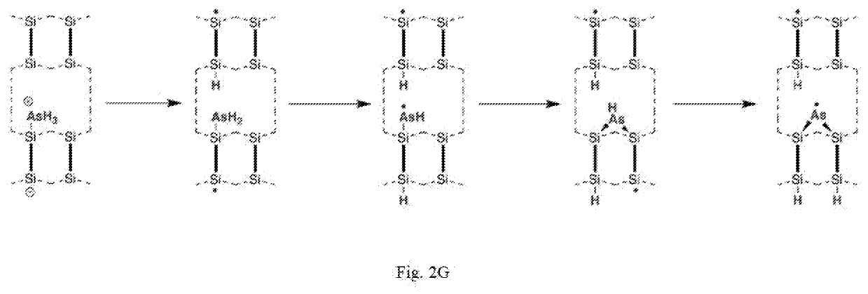

FIGS. 2A to 2F schematically illustrates a surface of the semiconductor lattice at the corresponding steps of the method shown in the flow diagram of FIG. 1;

FIG. 2G shows the dissociation of an arsine molecule on a free silicon surface;

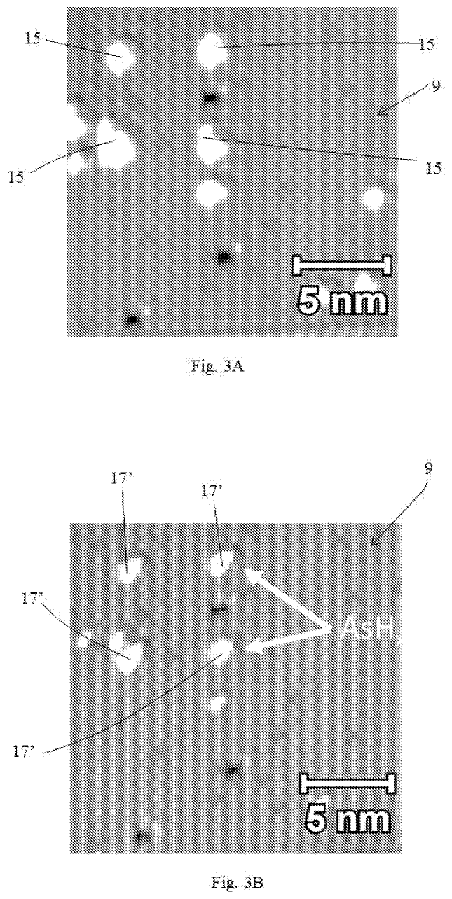

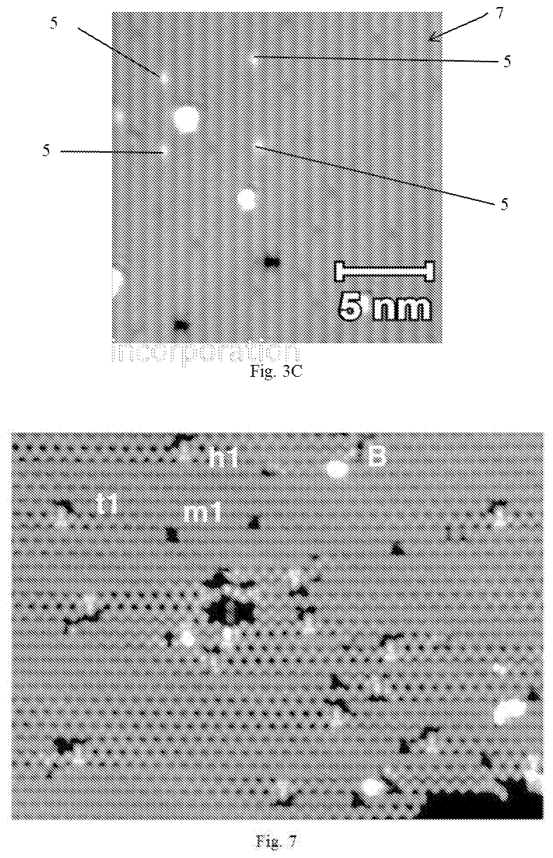

FIGS. 3A to 3C show scanning tunnelling microscope images of the surface of a lattice at certain steps of the method shown in the flow diagram of FIG. 1;

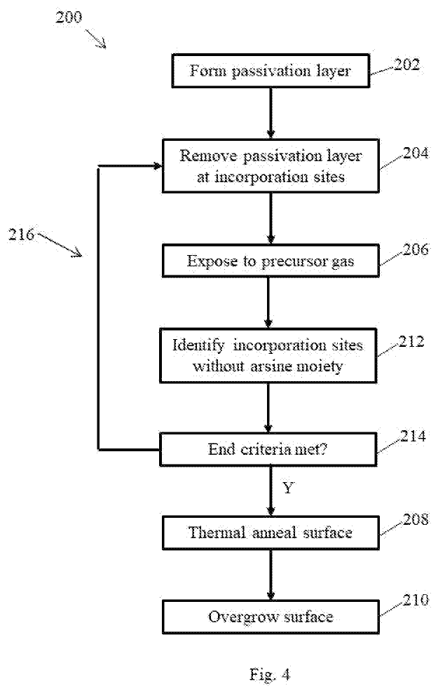

FIG. 4 shows a flow diagram of an alternative method for embedding a dopant atom in a surface of a semiconductor lattice;

FIG. 5 shows a flow diagram of a method of forming an atomic passivation layer;

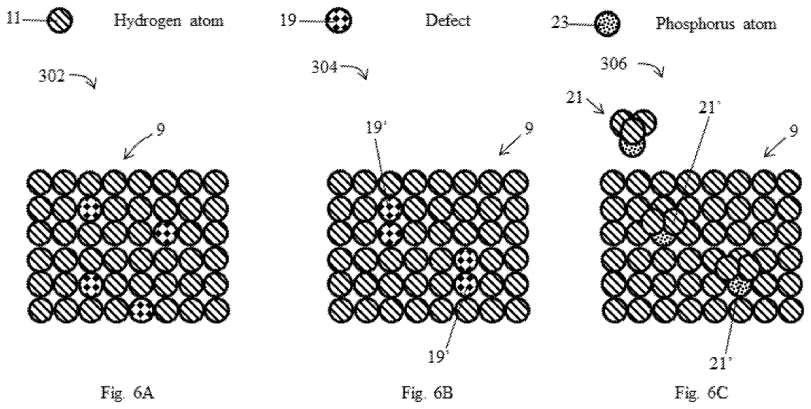

FIGS. 6A to 6C schematically illustrate the surface of the passivation layer in the corresponding steps of the method of FIG. 5;

FIG. 7 shows an example of an STM image of arsine doped Ge(001) surface formed at room temperature; and

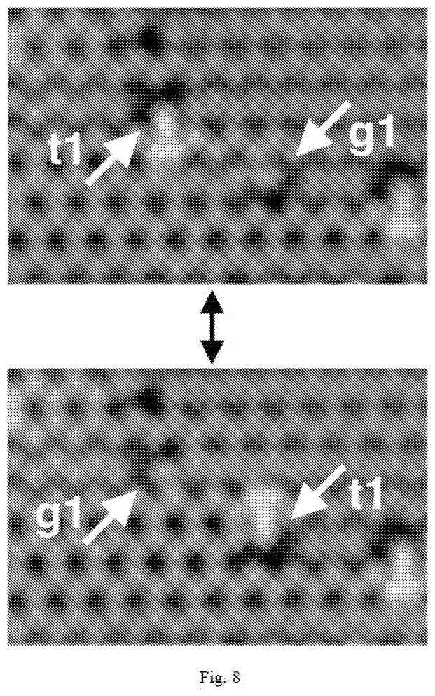

FIG. 8 shows an example of an STM of the exchange of a germanium ad-atom between two As—Ge—H heterodimer features in the surface shown in FIG. 7.

FIG. 1 shows a first method 100 of providing single dopant atoms 5 into lattice 1 of semiconductor atoms 3. FIGS. 2A to 2F show a schematic of the surface 7 of the lattice 1 at the different steps, as will be discussed below. The top row of FIGS. 2A to 2F shows a portion the lattice 1 in top down view, and the bottom row shows a portion of the lattice in side on view.

By the method 100 shown in FIG. 1, each dopant atom 5 take the place of a semiconductor atom 3 in the lattice 1. As will be discussed below, each dopant atom 5 is provided in a well-defined position, and is sufficiently spaced from other dopant atoms 5 such that the spin states of one dopant atom 5 do not affect the spin states of another dopant atom 5, and each dopant atom can be addressed by conducting contacts (not shown) without the electrical fields of the conducting contacts influencing each other.

In one example, as discussed below, arsenic dopant atoms 5 are incorporated into the (100) surface of a crystalline silicon lattice 1.

Prior to doping, the surface 7 of the silicon lattice 1 is cleaned. Various method of cleaning a surface of a semiconductor lattice 1 will be known to the person skilled in the art. This may include cycles of sputtering and annealing, thermal anneals cycled with cooling between them, cleaning with acetone and/or iso-propyl alcohol. FIG. 2A shows the prepared lattice 1.

The cleaning is carried out under vacuum conditions (<5×10⁻¹⁰ mbar). In addition, the steps 102, 104, 106, 108, 110 discussed below are carried out under vacuum conditions and at room temperature (for example between 15° C. and 30° C.).

Although FIGS. 2A to 2F shows the semiconductor atoms 3, dopant atoms 5 and hydrogen atoms 11 as being of the same size, it will be appreciated that this is not the case and the Figures are only schematic. However, in terms of bonding formed, the ratio of semiconductor atoms 3 in the surface layer to hydrogen atoms 11 in the passivation layer is 1:1 since each silicon atom 3 on the surface 7 has a single dangling bond (not shown) which is terminated by a single hydrogen atom 11.

At a first step 102 of the method 100 (see FIG. 2B), a passivation layer 9 is formed on the surface 7 of the lattice 1. The passivation layer 9 is formed of hydrogen atoms 11 and is a single atomic layer thick. Various methods for forming such a hydrogen passivation layer are known to the person skilled in the art.

At a second step 104 of the method (FIG. 2C), the tip 13 of a scanning tunnelling microscope (STM) is used to selectively remove hydrogen atoms 11 from the passivation layer 9, to expose the surface 7 of the lattice 1. The removed atoms 11 define incorporation sites 15 where dopant atoms 5 are to be incorporated.

The precise location of the STM tip 13 is controllable through the control routines of the STM. By controlling the position where the incorporation sites are 15 are formed, the location of the dopant atoms 5 can be controlled.

The size of the incorporation site 15 may be varied. For example, the incorporation site 15 may have an area of four silicon atoms 3, preferably arranged in a square (i.e. two adjacent silicon dimers) providing four dangling bonds. Alternatively, each incorporation site may be the size of a pair of silicon atoms 3 (a silicon dimer or two silicon dangling bonds), or a single silicon atom 3 (a single dangling bond).

The examiner shown in FIG. 2C shows an incorporation site having an area of two silicon atoms 3. FIG. 3A illustrates a scanning tunnelling microscope (STM) image showing four incorporation sites 15 of an area of two silicon atoms 3 formed in a passivation layer 9.

In a third step 106, the incorporation sites 15 are exposed to arsine gas, AsH₃ 17. In one example, the incorporation sites 15 are exposed to Arsine gas at 5×10⁻⁹ mbar for 5 minutes, although it will be appreciated that this is by way of example only, and a range of suitable pressures and times may be used.

At the incorporation sites 15, various AsHₓ moieties 17′ (where x=0 to 3) are adsorbed onto the silicon surface 7. Away from the incorporation sites 15, the passivation layer 9 prevents stops the moieties 17′ from adsorbing. FIG. 3B shows an STM image of AsHₓ moieties 17′ adsorbed onto the silicon surface 7 at the incorporation sites 15 shown in FIG. 3A.

At the incorporation sites 15, the moieties 17′ adsorbed will depend on the size of the incorporation site 15

During the adsorption, the AH₃ molecule 17 dissociates into the different AsHₓ moieties 17′, and the AsHₓ moieties 17′ bond to a silicon atom 3 on the surface 7. Depending on the AsHx moiety 17′, the arsenic atom 5 may bond to a single silicon atom 3 (referred to as an end configuration), or across the two silicon atoms 3 at the incorporation site 15 (referred to as a bridging configuration). At incorporation sites 15 where the AsHx moiety 17′ bonds to a single silicon atom 3, the dangling bond at the other silicon atom 3 at the incorporation site 15 bonds to a hydrogen 11 from a dissociated arsine molecule 17. The table below, which shows the percentage termination of dangling bonds at incorporation sites 15 of different sizes:

| No. of | % of incorporation | | | % of |
|---|---|---|---|---|
| dangling bonds | sites with AsHₓ | | | incorporation |
| in incorporation | (±5%) | | | sites with no |
| site | x = 0 | x = 1 | x = 2 | AsHₓ (±5%) |
| 1 | 0 | 0 | 10% | 90% |
| 2 | 0 | 0 | 80% | 20% |
| 4 | 10% | 60% | 30% | 0% |

Where x=1, the AsH moiety 17′ bonds in an end configuration. Where x=2, there is a mixture of moieties 17′ boned in the end and bridge configurations.

Typically, two arsenic atoms 6 are only seen at incorporation sites 15 having an area of six or more silicon atoms 5.

In a fourth step 108 of the method 100, the surface 7 is annealed to incorporate the arsenic dopant atoms 5 into the lattice structure 1, away from the surface 7. The annealing is performed by heating the sample to 350° C. for approximately 1 minute.

It will be appreciated that the annealing temperature may be chosen over a range of temperatures. The minimum temperature required is dictated by activation temperature of diffusion and desorption of hydrogen atoms 11 in the passivation layer 9. Incorporation of arsenic atoms 5 requires enough free silicon sites (dangling bonds) are available for full dissociation if the arsenic moieties 17′, as will be discussed below. These free sites are provided through the anneal, by diffusion of one or two dangling bond windows to the adsorption site, and/or by thermal desorption of the H atoms. The minimum temperature required for hydrogen desorption is 350° C., for diffusion of a single dangling bond is 275° C. and for diffusion of two dangling bonds is 375° C. The maximum temperature is determined by the activation temperature of recombinative AsHₓ desorption, which is around 450° C. Therefore, the anneal may be between 350° C. (to achieve hydrogen desorption) and 450° C. (to prevent desorption of arsenic)

It will also be appreciated that the time of the anneal, and heating ramp up and ramp down rates may also vary.

Arsine molecules 17 may fully dissociate at room temperature, when adsorbing to a free silicon surface 7, with no passivation layer 9. FIG. 2G shows the path by which an arsine molecule 17 adsorbs to a silicon surface 7 and dissociates. The steps are involved are:
The arsine molecule 17 is first datively adsorbed to the silicon surface, with an adsorption energy of −0.52 eV (determined by density functional theory (DFT) calculation;
In a first reaction step, the datively adsorbed arsine molecule 17 dissociates into an AsH2+H species by means of an inter-row hydrogen shift. This reaction transfers one hydrogen 11 atom to an adjacent dimer row, producing a hemihydride dimer. The DFT calculated adsorption energy for this structure is −1.85 eV. The DFT calculated activation barrier for this reaction step is only 0.23 eV, which corresponds to a reaction that is completed on a time scale of nanoseconds at room temperature. The inter-row hydrogen shift is kinetically preferable to the alternative, (and perhaps more intuitive) ondimer and interdimer hydrogen shifts, which have DFT calculated activation energies of 0.53 and 0.29 eV, respectively.
The second reaction step is also a hydrogen-shift reaction, which preferentially occurs in the ondimer direction to produce a dimer-end AsH+2H structure. This reaction transfers one hydrogen 11 atom on the same dimer as the AsH moiety 17′. The DFT calculated adsorption energy for this structure is −2.20 eV. The DFT calculated activation energy for this reaction step is 0.63 eV, corresponding to a reaction time scale of milliseconds at room temperature. The alternative reaction, in which the hydrogen atom shifts in the interdimer direction, has a slightly larger activation barrier of 0.72 eV, and is thus kinetically disfavored.
The dimer-end AsH+2H configuration containing a single-valent AsH fragment is a highly transient intermediate corresponding to an extremely shallow minimum on the potential energy surface. In a third reaction step, this species near-instantly stabilizes into the end-bridge AsH+2H species, in which the AsH fragment bridges between two dimer-ends. The DFT calculated adsorption energy for this structure is −2.62 eV. The DFT calculated activation energy for this reaction step is less than 0.05 eV
The final reaction step transfers a hydrogen atom from the AsH fragment to the silicon dangling bond at the opposite dimer end. This reaction produces the inter-row end-bridge As+3H. The DFT calculated adsorption energy for this structure is −3.09 eV. The DFT calculated activation energy for this reaction step is 0.89 eV; this is the rate-determining activation energy along the full dissociation path. This barrier is still low enough such that full dissociation of an adsorbing AsH₃ molecule into inter-row end-bridge As+3H will be completed on a time scale of tens of seconds.

For lithographic sites 17 having a size of four of fewer dangling bonds, the dissociation mechanism is halted partway along this reaction path, with an AsHₓ moiety bonded to the lattice 1. This is due to the lack of availability of dangling bonds for intra- or interdimer transfer of hydrogen atoms 11 due to the passivation layer 9. During the anneal, vacancies to complete the dissociation are generated by diffusion or desorption as discussed above. As also discussed above, the barrier to creating H-vacancy delivery is lower than that of AsHₓ recombinative desorption. Therefore, a high proportion of the arsenic atoms 5 are incorporated.

The below table illustrates the incorporation rate for different size incorporation sites 15 (i.e. the percentage of arsenic moieties 17′ bonded to the surface 7 which result in an incorporated arsenic atom 11):

| No. of | % of adsorbed |
|---|---|
| dangling | AsHₓ moieties |
| bonds in | which result in |
| incorporation | incorporated |
| site | As atom |
| 1 | 98 ± 2% |
| 2 | 98 ± 2% |
| 4 | 99 ± 1% |

As can be seen from FIG. 2E (bottom row), the dopant atom 5 moves into the lattice 7, and a silicon atom 3, which has been substituted by the dopant atom, is moved towards the surface. The arsenic atoms 11 are incorporated only into the top layer of the silicon 1. This means the silicon atoms 5 achieve three bonds to silicon atoms 3 in the top and second layer of the lattice 1.

In a final step 110, the silicon surface 7 is overgrown with further silicon, to bury the dopant atoms 5. It is believed that the hydrogen atoms 11 in the passivation layer 9 segregate to the surface as the overlayer is grown, meaning the passivation layer remains on the surface of the lattice 1. FIG. 3C shows the silicon surface 7 after the dopant atoms 5 adsorbed in FIG. 3B have been incorporated and overgrown. The dopant atoms 5 may be overgrown by a layer of any desired depth. Typically, the dopant atoms are overgrown by a layer between 2 and 20 nm.

The result of the method 100 is a silicon lattice 1 with arsenic dopant atoms 5 provided at known locations throughout the lattice 1. The location of each dopant atom 5 is known to within a limited number of atoms in the lattice 1, determined by the size of the lithographic sites. The spin of the valence in the electron can be used as a qubit for data storage or data processing. Alternatively, the spin of the nucleus can be used as a qudit for data storage or processing. The nuclear spin can retain its state for several days. In addition, the nuclear or electronic spin may be used for manipulation of other electronic devices.

The person skilled in the art will understand that various methods can be used to control, manipulate and read qubits and qudits. For example, highly doped regions (not shown) may be provided in the lattice 1 above or below the plane in which the dopant atoms 5 are incorporated to act as electrical contacts and/or gates. Alternatively, other conducting materials, such as gold, can be used as gates and contacts.

It will be appreciated that the method 100 discussed above can be scaled to provide any number of dopant atoms 5 in a surface. For example, a silicon wafer (not shown) could be provided with an array of dopant atoms 5, and cleaved into separate chips or devices. By this method, wafers having 1000s of qubits or qudits may be made.

Processes for automatic alignment and operation of the STM tip 13 will be apparent to the person skilled in the art. In one example, an array of cantilevered STM tips 13 or AFM tips may be used for faster processing. See, for example, P. Vettiger et al., “The “Millipede”—More than thousand tips for future AFM storage,” in IBM Journal of Research and Development, vol. 44, no. 3, pp. 323-340, May 2000, doi: 10.1147/rd.443.0323 or R. Huff et al., “Atomic White-Out: Enabling Atomic Circuitry through Mechanically Induced Bonding of Single Hydrogen Atoms to a Silicon Surface” in ACS Nano, vol. 11, no. 9, pp. 8636-8642 July 2017.

In the method 100 shown above, the position of the dopant atoms 5 is known to within a few silicon atoms 3 in the lattice 1, depending on the size of the incorporation site 15.

In general, the larger the incorporation site, the higher the proportion of sites are successfully doped, but the lower the accuracy the positioning of the dopant atom 5 is known. For example:
For an incorporation site 15 of four silicon atoms 11 in area, single dopant atoms 5 are incorporated at all but a negligible number of incorporation sites 15s, and the position is known to within a four atom area.
For example, for an incorporation site 15 of two silicon atoms 11 in area, single dopant atoms 5 are incorporated in approximately 80% of sites, and the position is known to within a two atom area.
For example, for an incorporation site 15 of one silicon atom 11 in area, single dopant atoms 5 are incorporated in approximately 10% of sites, and the position is known to within a single atom.

FIG. 4 illustrates an alternative method 200 that can used to provide even greater accuracy in the positioning of the dopant atoms 5. The method 200 of FIG. 4 is the same as the method 100 of FIG. 1 unless stated otherwise.

According 200 to the method of FIG. 4, a passivation layer 9 is formed in a first step 202, incorporation sites 15 are formed in the passivation layer 9 in a second step 204, and the incorporation sites 15 are exposed to arsine gas, AsH₃ 17 in a third step 206. The formation of the passivation layer 9, formation of incorporation sites 15 and exposing to arsine gas 17 is the same as in the corresponding steps 102, 104, 106 in the method 100 shown in FIG. 1. However, in the method 200 shown in FIG. 4, the area of each incorporation site 15 is only a single silicon atom 3 in the lattice 1 (i.e. a single dangling bond).

As discussed above, for an incorporation site of a single silicon atom 11 or a single silicon dimer, arsine moieties 17′ are not adsorbed at all sites. After the step 206 of exposing the incorporation sites 15 to arsine gas 17, the method 200 of FIG. 4 includes the step 212 of identifying, using an STM tip 13, the incorporation sites 15 where no moieties 17′ have been adsorbed. The STM tip 13 may be the same tip used to remove hydrogen atoms 11 to form incorporation sites 15, or a different STM tip 13.

In a next step 214 a check is carried to determine if an end criteria for the method has been reached, as will be discussed below in more detail.

If the end criteria has not been reached, the method 200 reverts to the second step 204.

At sites where the arsine moieties 17′ are not absorbed, dissociated hydrogen 11 from the arsine molecules will have filled the incorporation sites 15 by terminating the dangling bonds.

When the method 200 moves from the check step 214 to the step 204 of removing the passivation layer 9 at incorporation sites 15, the passivation layer 9 is only removed at the incorporation sites 15 that have been identified as not already having AsHₓ moieties 17′ adsorbed. Sites which have been determined to have moieties 17′ adsorbed are not exposed. The adsorbed moieties 17′ prevent further adsorption in later stages, and thus now form part of the passivation layer 9. Due to the energy of the bond between the moiety 17′ and the silicon surface 7, the adsorbed moiety 17′ will not desorb from the surface and recombine.

The loop 216 of forming of incorporation sites 15, exposing to arsine gas 17, identifying incorporation sites 15 without arsine moieties 17′, and checking the end criteria, is repeated iteratively until the end criteria is met. Then a thermal anneal is performed at step 208 to incorporate the arsenic atoms 5 from the absorbed moieties 17′. As discussed above, approximately 100% of adsorbed moieties result in absorption of an arsenic atom 5.

Finally, a silicon layer overgrown at step 210.

The thermal anneal and overgrowing are the same as the corresponding steps 108, 110 discussed in relation to the method 100 shown in FIG. 1.

Various end criteria may be used in the checking step 214. These include, for example:
100% adsorption of arsenic moieties 17′ at incorporation sites 15 (i.e. no empty sites identified);
The percentage (or number) of incorporation sites 15 with adsorbed arsenic moieties 17′ is above a threshold (where the threshold is below 100%);
A fixed number of loops have been completed. The number of loops may be determined based on a statistical likelihood of reaching 100% adsorption of arsenic moieties 17′ at incorporation sites (or the proportion of incorporation sites 15 with adsorbed moieties 17′ being above a threshold);
A fixed number of loops being completed without any change in the number of sites without arsenic moieties 17′ absorbed; or
A fixed time.

Other suitable end criteria may also be used.

By the method shown in FIG. 4, high levels of incorporation of dopant atoms 5 can be achieved with precise placement of the dopant atoms 5, such that the position in the dopant atoms is known to within a single atom in the lattice 1 when using incorporation sites of a single atoms, or to within two atoms in the lattice 1 when using incorporation sites 15 of a single silicon dimer. As with the method of FIG. 1, it will be appreciated that the steps 200 of FIG. 4 may be automated.

It will be appreciated that the iterative loop 216 need not only be used in combination with incorporation sites 15 having an area the size of a single silicon atom 3 or dimer. Where a high percentage of dopant incorporation is required (for any dopant, not just arsenic), the iterative process may be used to ensure the number of incorporation sites 15 with no dopant is reduced.

It will be appreciated that the greater the proportion of moieties 17′ adsorb in each loop, the fewer loops will be required to achieve a high level of overall incorporation. For example, where the incorporation sites 15 are a single dimer in size, 80% of sites have adsorbed moieties 17′ in a single loop, and so far fewer loops are required than when the incorporation sites 15 are a single atom in size, when only 10% of sites have adsorbed moieties 17′ in a single loop.

It will be appreciated that in some cases, incorporation sites may be increased in size in later loops, so that an end criteria may be achieved.

As discussed above, the passivation layer 9 is a single atom thick. It will be appreciated that the passivation layer 9 may include defects (holes) 19 where atoms of the passivation layer are omitted. These defects 19 have dangling silicon bonds, and may form (unwanted) incorporation sites 15. Even if only a single atom in size, this gives a 10% chance of adsorption and incorporation of an arsenic atom 5 in an undesired location.

FIG. 5 shows a method 300 of forming the passivation layer 9 that repairs/removes any defects 19. This method 300 is performed before the incorporation sites 15 are formed. FIGS. 6A to 6C show a schematic of the passivation layer 9 at the different steps, as will be discussed below. FIGS. 6A to 6C show the passivation layer 9 in top down view.

In a first step 302, the atomic layer of hydrogen atoms 11 is deposited as discussed above. As shown in FIG. 6A, a number of defects 19 (missing hydrogen atoms 11, also referred to as holes in the passivation layer 9) are present. The defects 19 are single missing atoms in size and are generally separated from each other.

In a second step 304, the passivation layer 9 is heated to approximately 200° C. This causes diffusion of the defects 19 to form defect pairs 19′ as shown in FIG. 6B.

In a third step 306, the passivation layer 9 is exposed to a precursor gas having molecules 21 containing phosphorus atoms 23 and hydrogen. For example, the precursor may be phosphine gas PH₃ 21. This dissociates into posphine moieties (usually PH₂) 21′ and an H atom, which are adsorbed at the defect pairs 19′, preventing the defects 19 from forming incorporation sites 15 when then passivation layer 9 is exposed to arsine gas 17.

The phosphine repaired passivation layer 9 is then used in the methods 100, 200 shown in FIG. 1 or 4. Arsenic moieties 17′ are unable to bond at defect sites 19′ since they are blocked by dissociated phosphine 21, and thus dopant arsenic atoms 5 are only incorporated at sites 15 where they are intended to be.

In the annealing step 108, 208 used to incorporate the arsenic atoms 5, the annealing temperature is sufficient that the dissociated phosphine desorbs and recombines rather than being incorporated into the lattice 1.

During the step 304 of heating the passivation layer 9 as part of repairing defects 19, the layer should be heated to a temperature sufficient to cause diffusion of the defects 19 to form defect pairs 19′ but lower than would cause any material changes to the lattice 1. Therefore, the layer should be heated to a minimum of 275° C. and to a temperature not higher than 350° C. . . . As discussed above, this ensures diffusion of hydrogen vacancies, but does not cause hydrogen desorption.

It may be that a small number of single dangling bond sites remain in the resits. However, as discussed above, over 90% of these sites will be reterminated, and so the amount of defects in the resist can be considered negligible.

It will be appreciated that the process 300 shown in FIG. 5 is optional, and need not be used. Furthermore, this process may be used when incorporating any dopant, and not just arsenic.

In the methods 100, 200 discussed above, arsenic dopant is incorporated into a silicon lattice 1.

It will be appreciated that arsenic dopant may also be incorporated into other semiconductor lattices 1. For example, a germanium lattice may be used instead of silicon.

The inventors have surprisingly found that the arsenic atom 5 from the arsine moieties 17′ is incorporated into the (001) surface of a germanium lattice 1 on adsorption at room temperature, so no annealing process is required. In other words, the arsine/germanium system proceeds from the state shown in FIG. 2D to the state shown in FIG. 2E without requiring any heating (or other energy transfer) as set out in step 108. This occurs at all but a negligible number of incorporation sites 15.

In the following discussion, STM experiments were performed in an Scienta Omicron GmbH low-temperature STM system operating at room temperature and under ultrahigh vacuum <5×10⁻¹⁰ mbar. High resistivity (1-100 Ωcm antimony doped) germanium 001-oriented samples were degassed overnight at 200° C., then heated to 760° C. by direct current heating for 1 hour. The samples were subsequently cleaned by repeated cycles of sputtering (1.2 kV, 10 mA, 30 min) and direct current annealing (700° C., 30 min). Sample preparation was then completed with three 30s anneals to 760° C., with a 25° C./min cool down from 600° C.

An infrared pyrometer (IMPAC IGA50-LO plus) was used to measure the sample temperature, providing absolute temperature measurements accurate to ±30° C.

Arsine dosing was performed in-situ with the STM tip macroscopically retracted. The samples were exposed to 99.999% purity arsine (ATMI Inc.) with a total chamber pressure of 1×10⁻¹⁰ mbar. After arsine dosing, the STM tip was reapproached and imaging started within 15 minutes of dosing.

Adsorption energies, ΔE, of surface structures arising from the adsorption and dissociation of arsine on Ge(001) were calculated as formation energies of adsorption as follows:

$$Δ E = {E}_{( cluster + A s H 3 )} - {E}_{( c l u s t e r )} - {E}_{( A s H 3 )}$$

Where E_{cluster} is the total energy of the bare germanium cluster, E_{(cluster+AsH3)} is the total energy of the cluster with an adsorbed or dissociated arsine molecule, and EAsH₃ is the total energy of a gas phase arsine molecule.

In some of the adsorption structures considered here, a germanium atom has been displaced away from the adsorption site to a location further away than can be accommodated by the three-dimer cluster. In this case, the adsorption energy is calculated as follows,

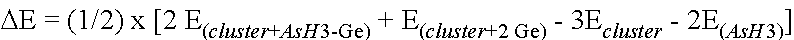

Where E_{(cluster+AsH3-Ge)} is the total energy of the cluster with a dissociated arsine molecule and one missing Ge atom and E_{(cluster+2Ge)} is the total energy of a cluster with a Ge—Ge ad-dimer, bridging perpendicular between two surface dimers. These ad-dimers are directly observed in experiments and are therefore the correct reference to account for the displaced germanium atoms in our calculations.

FIG. 7 shows an overview STM image of a germanium (001) surface dosed with arsine at room temperature. Rows of germanium dimers run horizontally across the image and form either a buckled c(4×2) configuration or a more symmetric appearing 2×1 configuration. Features related to arsine dosing are labelled B, h1, m1, and t1, and examples of these are highlighted by boxes.

The B feature is the brightest feature observed and appears as a single protrusion on top of a dimer row and in the position mid-way between two adjacent dimers. The type of feature labelled “B” was also observed shifting position on the surface, which is another known characteristic of germanium ad-dimers at room temperature. The existence of germanium ad-dimers on the surface after AsH₃ dosing suggests that arsenic atoms have incorporated into the surface, ejecting germanium atoms in the process.

The m1 feature is the most abundant feature after arsine dosing and it appears as two adjacent dark dimers. This feature is not perfectly symmetric, but instead it appears slightly less dark in one corner. This feature is assigned to the following structure:

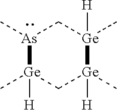

This is a fully dissociated arsine molecule, resulting in a surface-incorporated arsenic atom and three adsorbed hydrogen atoms; the hydrogen atoms 11 are bonded such that the result is a hydrogen-terminated arsenic-germanium heterodimer (As—Ge—H) and a monohydride dimer (H—Ge—Ge—H). This feature images less brightly than the surrounding bare germanium dimers due to the absence of the germanium dimer n-bonds caused by the adsorption of the three hydrogen atoms, and the formation of a lone pair on the arsenic atom. The slightly less-dark site in one corner of the feature is attributed to the arsenic atom.

The t1 and h1 features are three dimers wide. The t1 feature exhibits a complicated appearance and spans two dimer rows while the h1 feature exhibits a single dark dimer adjacent to two protrusions positioned asymmetrically about the dimer row.

The h1 feature is assigned to a hydrogen-terminated arsenic-germanium heterodimer (As—Ge—H) and two adsorbed hydrogen atoms. However, in this case, the two hydrogen atoms are adsorbed to the ends of two adjacent dimers to form two germanium hemihydride dimers (Ge—Ge—H), rather than to a single dimer as was the case for m1. The two protrusions observed in the STM image are produced by the two germanium dangling bonds of the hemihydride dimers, as highlighted by the circles in structural schematic below:

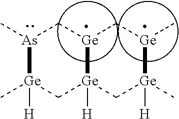

Occasional transitions are observed between this feature and several other three-dimer wide features. One or both of the asymmetric protrusions changes from the top of the dimer row to the bottom. This is attributed to one hydrogen or both atom moving from one side of the germanium dimer to the other. Where one hydrogen atom moves, this is referred to as either h2, and where both hydrogen atoms moves this is referred to as h3.

In a further transition, two protrusions of hemihydride dimers with the hydrogen atoms on the same side of the germanium dimer merge together to form a single protrusion. This is caused by the capture of a single germanium ad-atom to the germanium dangling bonds of the two hemihydride dimers in an end-bridge bonding configuration, as shown below:

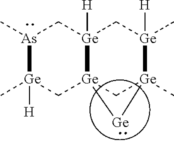

This is referred to as a g1 feature. In a final transition, the g1 feature may become the two-dimer row spanning feature t1 mentioned above (FIG. 1f).

It was observed that the protrusion produced by the ad-atom of the g1 feature increased in size and intensity. Therefore, a phason defect (i.e., a defect where two adjacent dimers become statically buckled in the same direction) may be pinned by a g1 feature on the adjacent dimer row. The spontaneous local pinning of a phasons is only expected at very low temperatures. Thus, there is believed to be a chemical origin for this pinning, specifically the capture of a second germanium ad-atom to form a dimer-trough bridging germanium ad-dimer, as shown below:

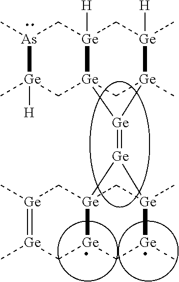

This structure explains both the enlargement of the protrusion at the site of the ad-atom in structure g1, and also the dimer pinning that causes the phason-like defect.

The transitions h3→g1 and g1→t1 thus arise from the dynamic capture of germanium ad-atoms. These ad-atoms are bound in g1 or t1 features, but are occasionally able to overcome the diffusion barriers at room temperature to leave one feature and be captured at another. Two examples of such transitions are shown in FIG. 8, which show both the source and the destination of a transiting germanium ad-atom.

The upper panel of FIG. 8 shows an STM image where a t1 and g1 feature are separated by a space of three dimers in the horizontal direction, and a single germanium dimer row in the vertical direction. The lower panel of FIG. 8 shows a subsequent image of the same area of the surface, where the t1 feature has become a g1 feature and vice versa, mediated by the exchange of a germanium ad-atom between them. This exchange is observed switching back and forth several times in successive STM images, confirming the reversibility of these transitions.

Further insight into the dynamics of the surface is obtained by counting the feature transitions between successive STM images. The average time between images was 9 minutes, and the imaging parameters were −1.5 V, 200 pA. Table 1 shows a count of transitions observed within a 50×50 nm² scan over a period of 12 hours. There is a strong symmetry to the table about the diagonal, as expected for reversible transitions.

TABLE 1

| | To: | | | |
|---|---|---|---|---|
| From: | h1/h3 | h2/h2* | g1 | t1 |
| h1/h3 | 15 | 36 | 8 | 0 |
| h2/h2* | 36 | 42 | 1 | 0 |
| g1 | 11 | 1 | 0 | 40 |
| t1 | 0 | 0 | 41 | 0 |

The largest number of transitions, 56% of the total number of observed transitions (129 out of 231), involve the shifting of hydrogen atoms across the dimer row to cause transitions among h1, h2, and h3 features. The next largest category are the ad-atom exchange transitions g1↔t1, which account for 35% of the total. Transitions between h1-h3 and g1 were relatively rare, accounting for 9% of all transitions; this demonstrates that the majority of ad-atom transitions are exchanges between dimer t1 and ad-atom g1 configurations. No transitions were observed between the h1-h3 and t1 structures, which can be understood since the g1 structure is intermediate between h1-h3 and t1.

Also notable is the absence of g1↔g1 or t1↔t1 transitions. Experimentally these would appear as a mirror symmetry transition about the dimer row, but such transitions are extremely unlikely given the structural assignments used.

The experimental observations are support by density functional theory (DFT) calculated formation energies. Each of the experimentally observed structures were calculated, and it was found that the formation energies for h1-h3 are all equal at −2.8 eV, and structure g1 is nearly equal at −2.9 eV. The closeness of these energies suggests the possibility of reversible transitions between these structures.

Structure m1 is slightly more stable at −3.1 eV. In addition, the energies for a wide range of AsHx+(3−x)H adsorption configurations have been calculated; the most stable of these are a AsH+2H configuration and an As+3H configuration; both have formation energies of −2.2 eV. Thus, a large energy gain (0.6 eV) is seen for the incorporation of arsenic into the top surface layer, and a very large overall energy gain for surface incorporation (~3 eV) compared to arsine in the gas phase. These large energy gains are the driving force underpinning the surface incorporation of arsenic into Ge(001) at room temperature.

As a further confirmation of this interpretation, it was checked that the densities of ejected germanium and incorporated arsenic are equal. Feature t1 is one of the most common features that was observe and this accounts for 30±11% of all arsenic-germanium heterodimer features (m1, h1-h3, g1, and t1) that were observed. The g1 features occur less frequently, accounting for 9±4% of heterodimer features, while the number of B site germanium ad-dimers is equivalent to 15±5% of the number of heterodimer features. Thus, noting that each t1 and ad-dimer feature contains two germanium atoms, 99±25% of the germanium atoms ejected onto the surface results from the incorporation of arsenic are accounted for.

It will be appreciated that germanium may be used in place of silicon in any of the methods 100, 200 discussed above. Furthermore, germanium may be used in any other suitable incorporation process.

Whilst it will be appreciated from the above that incorporating arsenic dopant in germanium does not require an annealing step, annealing (for example to a temperature of 140° C.) may be used to reduce surface defects. The temperature of the anneal may generally be lower than is typically required for incorporation of arsenic into silicon, and will not cause migration of doping atoms. Furthermore, onset of desorption of hydrogen atoms from a surface of germanium occurs at lower temp than for silicon, likely <250 C. Therefore, any temperatures discussed above relation to silicon, which are dictated by the desorption of hydrogen atoms may be modified accordingly.

Any of the above methods 100, 200 may include the optional step of annealing the semiconductor lattice 1 prior to applying the passivation layer 9. This may flatten the surface 7 of the lattice 1 prior to any processing. Techniques for such annealing steps are known in the art. For example, the semiconductor may be heated to high temperatures (>500° C.), and heating phases may be cycled with sputtering and or cooling.

In the above, a single species of dopant is provided. However, further processing steps are discussed for incorporating the resulting structure into an electronic device. It will be appreciated that this may involve doping regions of the lattice structure with other dopants, such as phosphorus. The additional dopant may be provided above or below the plane of the arsenic dopant and may also be included by hydrogen desorption lithography, involving the steps of:
(1) Applying an atom thick hydrogen passivation layer;
(2) Exposing incorporation sites;
(3) Exposing a precursor gas having molecules including the dopant atom and hydrogen atoms; and
(4) (If necessary) thermal annealing to incorporate the dopant atoms.

When incorporating phosphorus, for example, the incorporation sites should be exposed to the precursor gas at temperatures below 100 K. or the incorporation sites must be larger, in order to achieve the same accuracy in placement. However, it may be that for other dopants, the same precision is not required. Alternative processes may also be used for including other dopants.

In the above, single atoms are incorporated for providing qubits (or qudits). However, it will be appreciated that qubits/qudits (or devices for control or readout of qubits/qudits) can also be formed by quantum dots or wires or two dimensional electron gasses (sheets), formed by small clusters of dopant atoms 5 which still exhibit quantum properties. Larger structures of dopant atoms 5, exhibiting bulk properties, may also be provided. By making incorporation sites 15 larger, such areas of dopant atoms 5 can be formed. It will be appreciated that, for similar reasons as set out above, the incorporation site 15 for forming a quantum dot of arsenic dopant atoms will be smaller than forming a similar size quantum dot of phosphorus atoms.

In the above, an STM tip 13 is used to remove the passivation layer 9 at the incorporation sites 15, and, where necessary, identify sites 15 without arsine moieties 17′ absorbed. This is by way of example only. Any suitable method for removing atoms 11 from the passivation layer 9 may be used. For example, electron beam (ebeam) and STM scanning microscopes may be used.

In some of the above methods, a step of thermal annealing is used to incorporate the adsorbed dopant atoms 5. However, this is by way of example only. Any suitable method of energy transfer may be used. For example, energy may be transferred through an STM tip or an ebeam.

In the examples discussed above, the passivation layer 9 is hydrogen and the molecules of the precursor gas includes hydrogen in addition to phosphorus or arsenic. On other examples, different passivation layers may be used, and the molecules of the precursor gas may include the same or different atoms as the passivation layer.

Arsine and phosphine are given as examples of precursor gasses for applying dopant and repairing defect 19 in the passivation layer. These are by way of example only and other suitable precursor gases for applying phosphorus and arsenic may be used.

It will be appreciated that high levels of incorporation at room temperature, as discussed above, can be achieved where the energy barrier of the diffusion and/or desorption of the passivation layer 9 is lower than the desorption of the precursor moieties 17′, such that the dopant preferentially incorporates, rather than dissociates.

In the above discussions, DFT calculations were performed using the B3LYP hybrid exact-exchange functional, atom-centred Gaussian-type orbital basis sets, and methods of energy computations and structure optimisation as implemented in the Gaussian 09 or Gaussian 16 software. Activation energies and adsorption menageries were calculated for various configurations of arsine on silicon (001) and germanium (001) surfaces using an approach referred to as a cluster composite model.

For modelling silicon, a Si₁₅H₁₆ or Si₅₄H₄₄ cluster model was used to represent the Si (001) surface, with corrections to minimise the effect of the finite cluster size. Reaction steps in FIG. 2G were calculated using a 3D2R cluster for the first step, and the 2DIR cluster with the hemihydride dimer represented by a separate cluster for the remaining steps.

For modelling on germanium, a compact Ge₂₁H₂₀ cluster model was used to represent the Ge(001) surface, describing three Ge—Ge dimers in the surface-closest atomic layer, and eight, four, and three atoms in the second, third, and fourth atomic layer, respectively. The twenty hydrogen atoms of the cluster provide a chemical termination for all germanium atoms other than those of the surface layer. These cluster-terminating hydrogen atoms were held in fixed positions during all geometry optimisations in order to simulate the strain that would be imposed by the surrounding surface and bulk atoms of an extended surface. All other atoms were fully relaxed.

For calculations on silicon, a 6-311G(2df,2pd) atom-centred basis was used.

In the calculations on germanium, two types of composite basis set are used, referred to in the following as large and small. Geometry optimisations and vibrational frequency calculations were conducted using the small basis, which is composed of the standard 6-311++G(d,p) basis set for all atoms of the adsorbate and the top surface layer of the cluster (i.e. the dimer atoms), a 6-311G(d,p) basis set for second layer atoms, and the core-pseudopotential LANL2DZ basis set for third and fourth layer atoms as well as the cluster-terminating hydrogen atoms. Following geometry optimisation, a single-point energy was calculated at the optimised structure using the large basis set, which is composed of the 6-311++G(2df,2pd) basis set for the adsorbate atoms and top surface layer and a 6-311G(2df,2pd) basis set for all other atoms. Thus, using quantum-chemical notation, the total energy, E, of a given structure is calculated as E_{SCF} (B3LYP/large//B3LYP/small)+ZPE(B3LYP/small).

1. A method of incorporating arsenic dopant atoms in defined locations of semiconductor lattice, the method comprising:
(i) forming a passivation layer on a surface of the semiconductor lattice;
(ii) selectively removing the passivation layer at one or more incorporation sites to reveal the surface of the semiconductor lattice; and
(iii) exposing the incorporation sites to a dopant precursor gas such that dopant precursor moieties including arsenic atoms adsorb to the surface of the semiconductor lattice in at least some of the incorporation sites, wherein arsenic dopant atoms are incorporated into the lattice at the incorporation sites.

2. The method of claim 1, wherein the step of exposing the surface to a dopant precursor gas is performed at room temperature.

3. (canceled)

4. The method of claim 3, wherein the semiconductor lattice is a silicon lattice.

5. The method of claim 1, wherein the method incudes the step of thermal annealing the surface layer to incorporate of the arsenic dopant atom(s) into the semiconductor lattice.

6. The method of claim 3, wherein the semiconductor lattice is a germanium lattice.

7. The method of claim 6, wherein on adsorption of the dopant precursor moieties, the dopant precursor molecule dissociates and the arsenic atom is incorporated in the semiconductor lattice in a manner that no energy transfer is required.

8. The method of claim 1 further comprising:
over growing the surface of the semiconductor lattice after the arsenic dopant atoms are incorporated.

9. The method of claim 1, wherein the area of each incorporation site is at most four semiconductor atoms.

10. The method of claim 9, wherein:
arsenic dopant atoms are incorporated at 100% of incorporation sites that are four semiconductor atoms in area;
arsenic dopant atoms are incorporated at 80% of incorporation sites that have the area of a semiconductor dimer; and
arsenic dopant atoms are incorporated at 10% of incorporation sites that have the area of a single semiconductor atom.

11. (canceled)

12. (canceled)

13. The method of claim 9, further comprising, prior to incorporating the arsenic atoms:
(a) identifying incorporation sites where adsorption of arsine has failed and an atom of the passivation layer has readsorbed;
(b) selectively removing the passivation layer to expose the identified incorporation sites; and
(c) exposing the identified incorporation sites to the dopant precursor gas such that the dopant precursor moieties adsorb to the surface of the semiconductor lattice at the identified incorporation sites.

14. The method of claim 13, further comprising:
repeating steps (a) to (c) at least once in an iterative manner; and
(d) incorporating the arsenic atoms into the semiconductor lattice.

15. The method of claim 1, comprising, between step (i) and step (ii):
heating the passivation layer to cause diffusion of defects in the passivation layer such that defect group together in pairs; and
exposing the passivation layer to a further precursor gas comprising further precursor molecules including the same atoms as the passivation layer, to fill the holes in the passivation layer.

16. (canceled)

17. The method of claim 15, wherein the further precursor gas comprises posphine PH₃.

18. The method of claim 15, wherein the passivation layer is heated to at least 200° C. to cause diffusion of holes in the passivation layer.

19. The method of claim 1, comprising:
forming a second passivation layer on a surface of the semiconductor lattice;
selectively removing the second passivation layer at one or more second incorporation sites to reveal the surface of the semiconductor lattice; and
exposing the second incorporation sites to a second dopant precursor gas such that second dopant precursor moieties including atoms of a second dopant, different to arsenic, adsorb to the surface of the semiconductor lattice in at least some of at the second incorporation sites,
wherein atoms of the second dopant are incorporated into the lattice at the second corporation sites.

20. The method of claim 1, wherein the step of selectively removing the passivation layer at one or more incorporation sites to reveal the surface of the semiconductor lattice is performed by one of:
scanning tunnelling microscopy;
an array of scanning tunnelling microscopy probes; and
electron beam microscopy.

21. (canceled)

22. The method of claim 1, comprising the step of, prior to forming the passivation layer on the surface of the semiconductor lattice, annealing the surface of the semiconductor lattice to form a flat surface on an atomic scale.

23. The method of claim 1, wherein the passivation layer comprises atomic hydrogen.

24. The method of claim 1, wherein the dopant precursor gas comprises arsine AsH₃.

25. The method of claim 1, wherein the energy barrier of the diffusion and/or desorption of atoms of the passivation layer is lower than the energy barrier of desorption of the precursor moieties from the surface of the semiconductor lattice.
